(19) United States
(12) Patent Application Publication
(10) Pub. No.: US 2015/0241785 A1
(43) Pub. Date: Aug. 27, 2015

(54) METHOD OF MANUFACTURING SEMICONDUCTOR DEVICE

(71) Applicant: KABUSHIKI KAISHA TOSHIBA, Minato-ku (JP)

(72) Inventor: Masao ISHIKAWA, Neyagawa-shi (JP)

(73) Assignee: KABUSHIKI KAISHA TOSHIBA, Minato-ku (JP)

(21) Appl. No.: 14/315,858

(22) Filed: Jun. 26, 2014

Related U.S. Application Data
(60) Provisional application No. 61/943,198, filed on Feb. 21, 2014.

(51) Int. Cl. G03F 7/26; G03F 7/20

(52) U.S. Cl. CPC G03F 7/26; G03F 7/2022

(57) ABSTRACT

In one embodiment, a method of manufacturing a semiconductor device includes forming a first film to be used to form a first pattern on a substrate, and forming a second film to be used to form a second pattern on the first film. The method further includes forming a third pattern formed of a third film on the second film. The method further includes processing the second film by using the third pattern to form the second pattern formed of the second film, and processing the first film by using the second pattern to form the first pattern formed of the first film. The method further includes slimming the first pattern by dry etching.

### CROSS REFERENCE TO RELATED APPLICATION

This application is based upon and claims the benefit of priority from the prior U.S. Provisional Patent Application No. 61/943,198 filed on Feb. 21, 2014, the entire contents of which are incorporated herein by reference.

### FIELD

Embodiments described herein relate to a method of manufacturing a semiconductor device.

### BACKGROUND

A fine pattern can be formed, for example, by a sidewall transfer process. In recent years, studies have been made to develop a double sidewall transfer process that can form a finer pattern. In this case, a core material pattern formed by the double sidewall transfer process is slimmed by wet etching. However, a decrease in width of the fine pattern reduces the slimming amount of the core material pattern, so that the sliming amount approaches a lower limit of the slimming of the core material pattern that can be achieved by the wet etching. Also, the decrease in width of the fine pattern leads to a need for more accurate control of the slimming amount of the core material pattern, so that the slimming amount approaches a limit of the accuracy that can be achieved by the wet etching. This makes it difficult to control the slimming of the core material pattern, and makes it difficult to form the fine pattern with a desired width.

### BRIEF DESCRIPTION OF THE DRAWINGS

FIGS. 1A to 4B are cross-sectional views showing a method of manufacturing a semiconductor device of a first embodiment, and

FIGS. 5A and 5B are cross-sectional views showing a method of manufacturing a semiconductor device of a second embodiment.

### DETAILED DESCRIPTION

Embodiments will now be explained with reference to the accompanying drawings.

In one embodiment, a method of manufacturing a semiconductor device includes forming a first film to be used to form a first pattern on a substrate, and forming a second film to be used to form a second pattern on the first film. The method further includes forming a third pattern formed of a third film on the second film. The method further includes processing the second film by using the third pattern to form the second pattern formed of the second film, and processing the first film by using the second pattern to form the first pattern formed of the first film. The method further includes slimming the first pattern by dry etching.

### First Embodiment

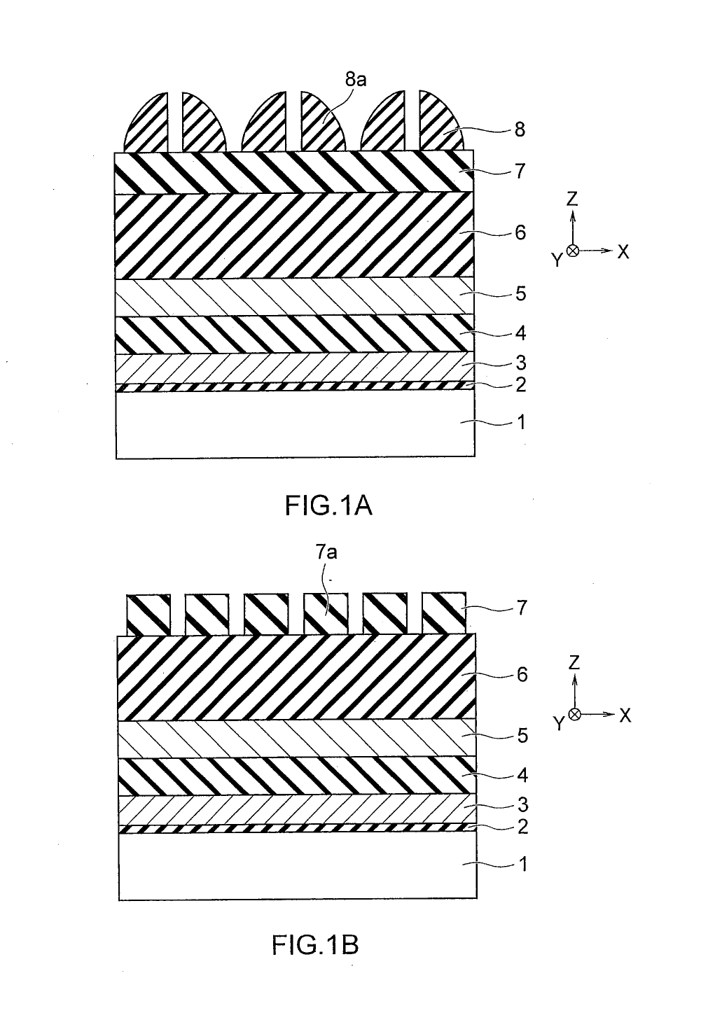

FIGS. 1A to 4B are cross-sectional views showing a method of manufacturing a semiconductor device of a first embodiment.

[FIG. 1A]

As shown in FIG. 1A, a gate insulator material 2, a gate electrode material 3, a first hard mask layer 4, a second hard mask layer 5, a core material layer 6 and a third hard mask layer 7 are formed on a substrate 1 in this order. The core material layer 6 is an example of a first film. The third hard mask layer 7 is an example of a second film.

An example of the substrate 1 is a semiconductor substrate such as a silicon substrate. FIG. 1A shows X and Y directions which are parallel to a surface of the substrate 1 and are perpendicular to each other, and a Z direction which is perpendicular to the surface of the substrate 1. In this specification, the +Z direction is represented as an upward direction, and the −Z direction is represented as a downward direction. For example, the positional relationship between the substrate 1 and the core material layer 6 is expressed such that the core material layer 6 is positioned above the substrate 1.

The gate insulator material 2 and the gate electrode material 3 are workpiece layers for the method of manufacturing the semiconductor device of the present embodiment. Examples of the gate insulator material 2 are a silicon oxide film and a high permittivity film (high-k film) having a larger permittivity than the silicon oxide film. Examples of the gate electrode material 3 are a polysilicon layer and a metal layer. An example of the metal layer is a tungsten (W) layer.

An example of the first hard mask layer 4 is a silicon oxide film. An example of the second hard mask layer 5 is a polysilicon layer.

The core material layer 6 of the present embodiment is a low permittivity film (low-k film) having a smaller permittivity than the silicon oxide film. The core material layer 6 includes an alkyl group as a functional group. An example of the low permittivity film is a low permittivity oxide film containing silicon and oxygen and including a methyl (CH₃) group. The core material layer 6 is formed, for example, by chemical vapor deposition (CVD). An example of the third hard mask layer 7 is an amorphous silicon layer.

As shown in FIG. 1A, sidewall patterns 8a formed of a sidewall film 8 is formed on the third hard mask layer 7. The sidewall film 8 is an example of a third film. The sidewall patterns 8a are an example of a third pattern.

The sidewall patterns 8a of the present embodiment are formed by a double sidewall transfer process. The sidewall patterns 8a are formed, for example, by forming resist patterns (or hard mask patterns) on the third hard mask layer 7, depositing the sidewall film 8 on the resist patterns, and etching back the sidewall film 8. An example of the sidewall film 8 is a silicon nitride film.

[FIG. 1B]

As shown in FIG. 1B, the third hard mask layer 7 is processed by using the sidewall patterns 8a to form hard mask patterns 7a formed of the third hard mask layer 7. The hard mask patterns 7a are an example of a second pattern. The third hard mask layer 7 is processed, for example, by dry etching using a mixed gas of a hydrogen bromide (HBr) gas and an oxygen (O₂) gas.

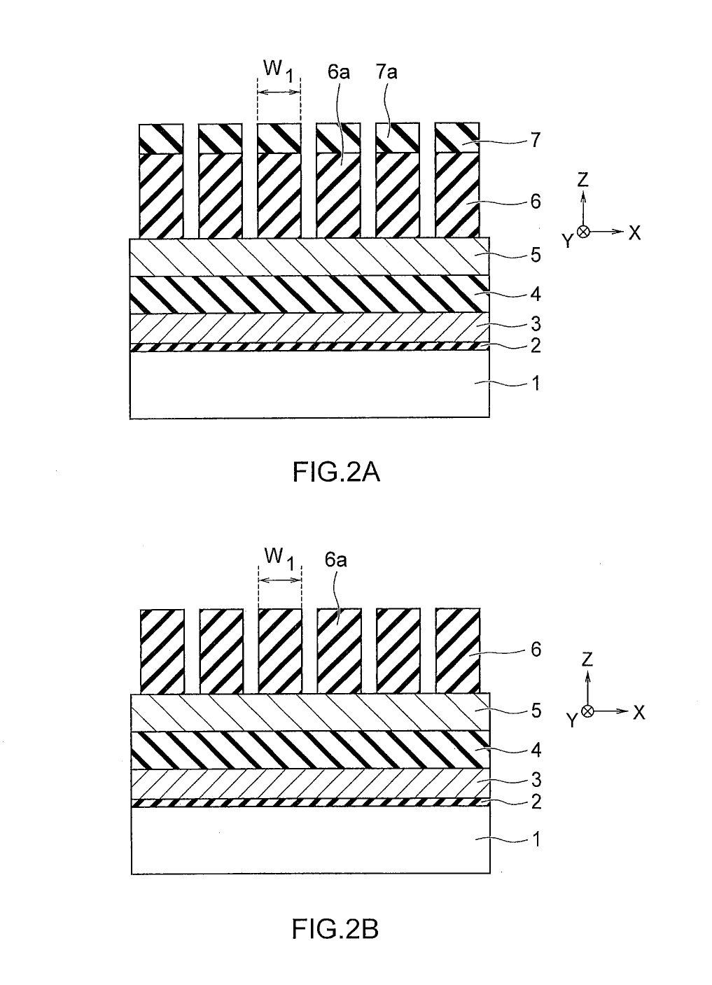

As shown in FIG. 1B, the sidewall patterns 8a are removed after the hard mask patterns 7a are formed. The sidewall patterns 8a are removed, for example, by wet etching.

[FIG. 2A]

As shown in FIG. 2A, the core material layer 6 is processed by using the hard mask patterns 7a to form core material patterns 6a formed of the core material layer 6. The core material patterns 6a are an example of a first pattern. The core material layer 6 is processed, for example, by dry etching using a mixed gas of a C_{X}F_{Y} gas and an O₂ gas, where “C” and “F” respectively denote carbon and fluorine, and “X” and “Y” are integers of one or larger.

[FIG. 2B]

As shown in FIG. 2B, the hard mask patterns 7a are removed after the core material patterns 6a are formed. The hard mask patterns 7a are removed, for example, by wet etching.

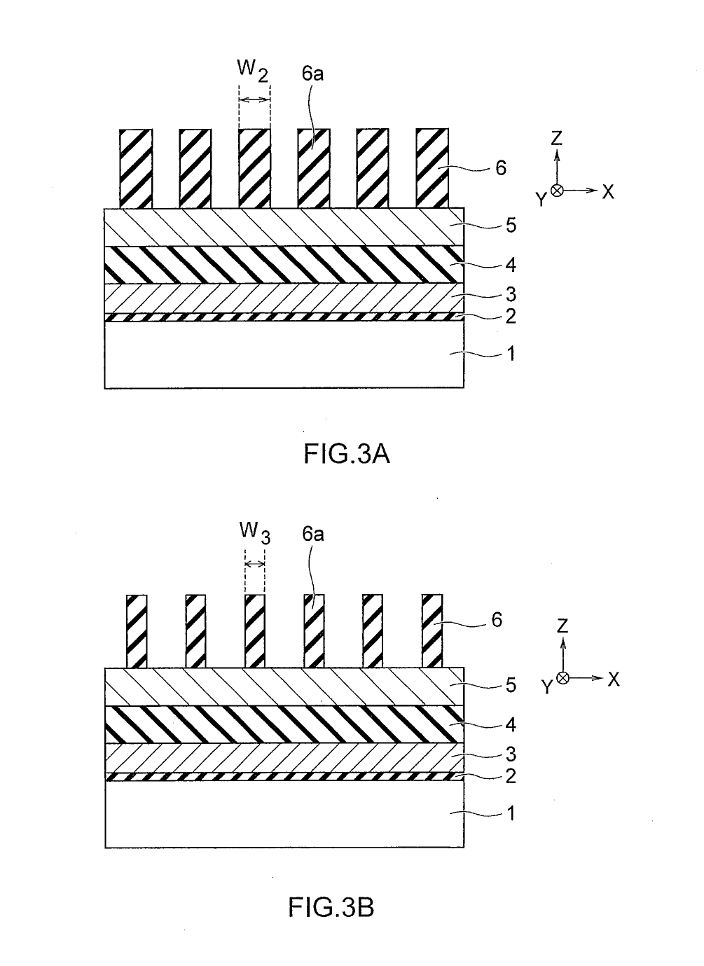

The core material patterns 6a of the present embodiment have shapes extending in the Y direction. Reference character W₁ denotes a width of the core material patterns 6a in the X direction. Specifically, reference character W₁ denote the width of the core material patterns 6a in the X direction before performing a shrink process and slimming described below. The core material patterns 6a of the present embodiment form line and space (L/S) patterns with a constant line width and a constant space width.

[FIG. 3A]

As shown in FIG. 3A, a shrink process of shrinking the size of the core material patterns 6a is then performed. The shrink process of the present embodiment is a removal process of removing the methyl group contained in the core material patterns 6a. The removal process need not remove all of methyl groups contained in the core material patterns 6a. It is sufficient for the removal process to remove a part of the methyl groups contained in the core material patterns 6a. The removal process uses, for example, an oxygen (O₂) gas or a hydrogen (H₂) gas.

According to the removal process of the present embodiment, the methyl groups contained in the core material patterns 6a are substituted with, for example, hydrogen atoms. As a result, the size of the core material patterns 6a is shrunk.

Reference character W₂ denotes the width of the core material patterns 6a in the X direction after performing the shrink process. A decrease in width of the core material patterns 6a by the shrink process of the present embodiment (W₁-W₂) is smaller than 10 nm, and approximately 6 nm for example.

The present embodiment employs the low permittivity film as the core material layer 6 because many available low permittivity films include methyl groups. According to the present embodiment, the shrink process for the core material patterns 6a can be achieved by using the low permittivity film as the core material layer 6. The core material layer 6 may be formed of a material other than the low permittivity film if the core material layer 6 is formed of the material which can perform the shrink process for the core material patterns 6a. Also, the functional group contained in the core material layer 6 may be any alkyl group other than the methyl group or may be a functional group other than the alkyl group if the removal process can be performed on the functional group.

[FIG. 3B]

As shown in FIG. 3B, the core material patterns 6a are then slimmed by dry etching after the shrink process is performed. Reference character W₃ denotes the width of the core material patterns 6a in the X direction after performing the slimming. A decrease in width of the core material patterns 6a by the slimming of the present embodiment (W₂-W₃) is smaller than 10 nm, and approximately 6 nm for example.

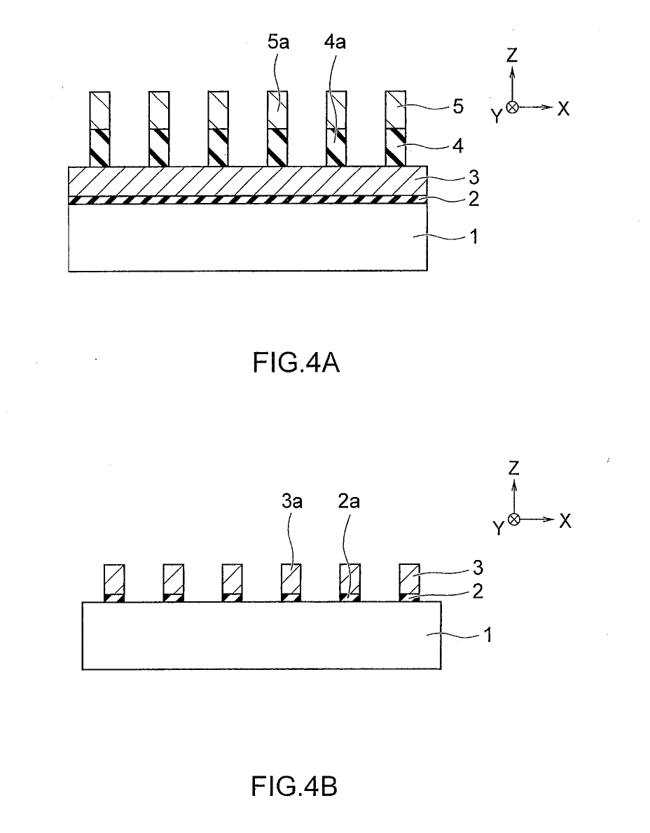

Furthermore, a decrease in width of the core material patterns 6a by the shrink process and the slimming of the present embodiment (W₁-W₃) is equal to or larger than 10 nm, and approximately 12 nm for example.

[FIG. 4A]

As shown in FIG. 4A, the first hard mask layer 4 and the second hard mask layer 5 are then processed by etching using the core material patterns 6a. As a result, hard mask patterns 4a and 5a which are respectively formed of the first hard mask layer 4 and the second hard mask layer 5 are formed.

[FIG. 4B]

As shown in FIG. 4B, the gate insulator material 2 and the gate electrode material 3 are processed by etching using the hard mask patterns 4a and 5a. As a result, gate insulators 2a and gate electrodes 3a which are respectively formed of the gate insulator material 2 and the gate electrode material 3 are formed.

Subsequently, diffusion layers, inter layer dielectrics, contact plug layers, via plug layers, interconnect layers and the like are formed in or on the substrate 1. In this way, the semiconductor device of the present embodiment is manufactured. The method of manufacturing the semiconductor device of the present embodiment makes it possible to form the gate electrodes 3a with the small width W₃.

### Shrink Process and Slimming of First Embodiment

Details of the shrink process and the slimming of the first embodiment will be described with reference to FIGS. 3A and 3B.

In general, the core material patterns 6a are slimmed by wet etching. The slimming by wet etching has however the following disadvantages. First, the slimming amount by wet etching is expected to be limited, so that the slimming with a slimming amount of less than 10 nm is expected to be difficult. Second, the accuracy of the slimming amount by wet etching depends on the type and concentration of an etchant, so that the accuracy that can be achieved by wet etching is expected to be limited.

In general, a smaller width W₃ of the gate electrodes 3a needs to be more accurately controlled. As a result, the slimming amount of the core material patterns 6a needs to be accurately controlled. However, the width W₃ of the gate electrodes 3a becomes smaller, the limited accuracy that can be achieved by wet etching acts disadvantageously.

In the present embodiment, the core material patterns 6a are slimmed by dry etching. This is because the slimming amount of the core material patterns 6a can be more accurately controlled by dry etching than by wet etching. Therefore, the slimming by dry etching is adopted in the present embodiment to make it possible to improve the accuracy of the slimming amount of the core material patterns 6a.

Furthermore, the shrink process for the core material patterns 6a is performed in the present embodiment before the core material patterns 6a are slimmed. This is because the shrink of the size of the core material patterns 6a generally reduces a dry etching rate for the core material patterns 6a, enabling the slimming amount of the core material patterns 6a to be accurately controlled. Therefore, the present embodiment adopts the shrink process before the slimming to enable the core material patterns 6a to be more accurately slimmed.

When the shrink process and the slimming are performed on the core material patterns 6a, the slimming amount (W₂-W₃) in the step shown in FIG. 3B need be smaller than 10 nm in some cases. As described above, performing such slimming by wet etching is difficult. However, since the slimming of the present embodiment is performed by dry etching, the core material patterns 6a can be slimmed even when the slimming amount is smaller than 10 nm.

In an example of the present embodiment, the decrease in width of the core material patterns 6a by the shrink process and the dry etching (W₁-W₃) is equal to or larger than 10 nm, and approximately 12 nm for example. According to the present embodiment, the process of decreasing the width of the core material patterns 6a by 10 nm or larger can be achieved by the shrink process and the dry etching instead of the wet etching. In this case, according to the present embodiment, the accuracy of the width W₃ of the gate electrodes 3a can be accurately controlled by the dry etching.

When the core material patterns 6a are slimmed by wet etching, the core material patterns 6a may collapse due to the surface tension of the etchant. The possibility that the core material patterns 6a collapse due to the surface tension of the etchant increases with decreasing the width W₃ of the core material patterns 6a. However, according to the present embodiment, the core material patterns 6a are slimmed by dry etching, so that such collapse of the core material patterns 6a can be avoided.

The third film of the present embodiment is the sidewall film 8. The third film may however be a film other than the sidewall film 8. Also, the workpiece layers for the method of manufacturing the semiconductor device of the present embodiment are the gate insulator material 2 and the gate electrode material 3. The workpiece layers may however be other layers. Additionally, the first hard mask layer 4 and the second hard mask layer 5 of the present embodiment may be replaced with a single hard mask layer or three or more hard mask layers.

### Second Embodiment

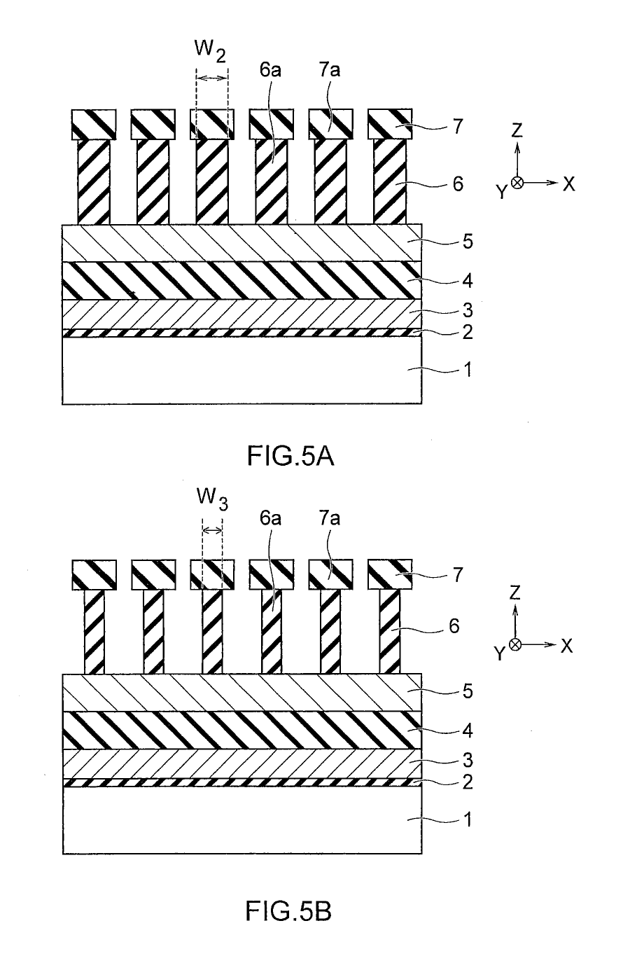

FIGS. 5A and 5B are cross-sectional views showing a method of manufacturing a semiconductor device of a second embodiment.

In the second embodiment, processes shown in FIGS. 5A and 5B are performed instead of the processes shown in FIGS. 2B to 3B.

In the processes shown in FIGS. 2B to 3A, the hard mask patterns 7a are removed after the core material patterns 6a is formed (FIG. 2A). Next, the shrink process for the core material patterns 6a is performed (FIG. 2B). The core material patterns 6a are then slimmed by dry etching (FIG. 3A).

In contrast, in the processes shown in FIGS. 5A and 5B, the shrink process for the core material patterns 6a is performed while the hard mask patterns 7a remain on the core material patterns 6a (FIG. 5A). As a result, the width of the core material patterns 6a becomes equal to W₂, and the width of the hard mask patterns 7a is kept longer than W₂. The core material patterns 6a are then slimmed by dry etching while the hard mask patterns 7a remain on the core material patterns 6a (FIG. 5B). As a result, the width of the core material patterns 6a becomes equal to W₃, and the width of the hard mask patterns 7a is kept longer than W₃. Subsequently, the hard mask patterns 7a are removed (or the removal of the hard mask patterns 7a is omitted), and the processes shown in FIG. 3B to FIG. 4B are performed.

According to the present embodiment, when the core material patterns 6a are slimmed, upper surfaces of the core material patterns 6a can be protected from the adverse effect of dry etching, for example.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a first film to be used to form a first pattern on a substrate;
forming a second film to be used to form a second pattern on the first film;
forming a third pattern formed of a third film on the second film;
processing the second film by using the third pattern to form the second pattern formed of the second film;
processing the first film by using the second pattern to form the first pattern formed of the first film; and
slimming the first pattern by dry etching.

2. The method of claim 1, comprising performing a shrink process of shrinking a size of the first pattern before the slimming.

3. The method of claim 2, wherein the shrink process is a removal process of removing a functional group contained in the first pattern.

4. The method of claim 3, wherein the removal process is performed by using an oxygen gas or a hydrogen gas.

5. The method of claim 3, wherein the functional group is an alkyl group.

6. The method of claim 1, wherein the first film is a low permittivity film.

7. The method of claim 2, wherein a decrease in width of the first pattern by the shrink process and the slimming is equal to or larger than 10 nm.

8. The method of claim 1, wherein a decrease in width of the first pattern by the slimming is smaller than 10 nm.

9. The method of claim 1, wherein the slimming is performed while the second pattern remains on the first pattern.

10. The method of claim 1, wherein the third pattern is a sidewall pattern formed by a double sidewall transfer process.

11. A method of manufacturing a semiconductor device, comprising:
forming a first film to be used to form a first pattern on a substrate;
forming a second film to be used to form a second pattern on the first film;
forming a third pattern formed of a third film on the second film;
processing the second film by using the third pattern to form the second pattern formed of the second film;
processing the first film by using the second pattern to form the first pattern formed of the first film;
performing a shrink process of shrinking a size of the first pattern; and
slimming the first pattern after the shrink process.

12. The method of claim 11, wherein the shrink process is a removal process of removing a functional group contained in the first pattern.

13. The method of claim 12, wherein the removal process is performed by using an oxygen gas or a hydrogen gas.

14. The method of claim 12, wherein the functional group is an alkyl group.

15. The method of claim 11, wherein the first film is a low permittivity film.

16. The method of claim 11, wherein a decrease in width of the first pattern by the shrink process and the slimming is equal to or larger than 10 nm.

17. The method of claim 11, wherein a decrease in width of the first pattern by the slimming is smaller than 10 nm.

18. The method of claim 11, wherein the slimming is performed by dry etching.

19. The method of claim 11, wherein the slimming is performed while the second pattern remains on the first pattern.

20. The method of claim 11, wherein the third pattern is a sidewall pattern formed by a double sidewall transfer process.
